(19) United States
(12) Patent Application Publication
(10) Pub. No.: US 2007/0210319 A1
(43) Pub. Date: Sep. 13, 2007

(54) Light Emitting Device and Manufacturing Method Thereof

(76) Inventor: Hyo Kun Son, Gwangsan-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/685,609

(22) Filed: Mar. 13, 2007

(30) Foreign Application Priority Data
Mar. 13, 2006 (KR) 10-2006-0023225

(51) Int. Cl. H01L 33/00

(52) U.S. Cl. 257/79

(57) ABSTRACT

Embodiments of a light emitting device are provided. A light emitting device can include a first electrode, a first condition type semiconductor layer, an active layer, a second conduction type semiconductor layer, a second electrode, and a substrate. The first conduction type semiconductor layer can be formed on the first electrode. The active layer can be formed on the first conduction type semiconductor layer. The second conduction type semiconductor layer can be formed on the active layer. The second electrode can be formed on the second conduction type semiconductor layer. The substrate is on the lateral sides of the first conduction type semiconductor layer, the active layer, and the second conduction type semiconductor layer.

### CROSS-REFERENCE TO RELATED APPLICATION

The present application claims priority under 35 U.S.C. § 119 to Korean Patent Application No. 10-2006-0023225 filed on Mar. 13, 2006, which is hereby incorporated by reference in its entirety.

### BACKGROUND OF THE INVENTION

A light emitting device can have a light emitting region including an ultraviolet wavelength region, a blue wavelength region, and a green wavelength region. For example, a GaN-based nitride semiconductor light emitting device can be used as a light emitting device.

In the GaN-based nitride semiconductor light emitting device, a buffer layer is formed on a sapphire substrate, and an n-GaN layer, an active layer and a p-GaN layer are formed on the buffer layer.

Also, after an electrode layer is formed on the n-GaN layer and the p-GaN layer, a current may be applied thereto so that light is generated at the active layer.

Meanwhile, since the sapphire substrate and the n-GaN layer have different lattice constants, dislocation is generated at a boundary between the sapphire substrate and the n-GaN layer.

To reduce this dislocation, the buffer layer is formed on the sapphire substrate to reduce a difference in a lattice constant between the sapphire substrate and the n-GaN layer.

However, there is a limit in reducing dislocation propagating to the n-GaN layer even when the n-GaN layer is formed on the buffer layer.

Also, when a high reverse voltage is applied to an electrode formed on the n-GaN layer or the p-GaN layer of the nitride semiconductor light emitting device, the active layer located most closely to the electrode is destroyed.

Furthermore, in the nitride semiconductor light emitting device, carriers are not uniformly supplied to the n-GaN layer depending on the position where the electrode is formed, so that resistance increases.

### BRIEF SUMMARY

An embodiment of the present invention is related to a light emitting device and a manufacturing method thereof that addresses and/or substantially obviates one or more problems due to limitations and disadvantages of the related art.

An embodiment of the present invention provides a light emitting device capable of reducing propagation of dislocation occurring in a substrate, and a manufacturing method thereof.

An embodiment of the present invention provides a light emitting device capable of swiftly supplying carriers, and a manufacturing method thereof.

An embodiment of the present invention provides a light emitting device having an enhanced electrostatic discharge (ESD) characteristic, and a manufacturing method thereof.

Additional advantages, objects, and features of the embodiments will be set forth in part in the description which follows and in part will become apparent to those having ordinary skill in the art upon examination of the following or may be learned from practice of the embodiment. The objectives and other advantages of the invention may be realized and attained by the structure particularly pointed out in the written description and claims hereof as well as the appended drawings.

An embodiment of the present invention provides a light emitting device comprising: a first electrode; a first conduction type semiconductor layer on the first electrode; an active layer on the first conduction type semiconductor layer; a second conduction type semiconductor layer on the active layer; a second electrode on the second conduction type semiconductor layer; and a substrate on lateral sides of the first conduction type semiconductor layer, the active layer, and the second conduction type semiconductor layer.

An embodiment of the present invention provides a light emitting device comprising: a substrate having an opening; a buffer layer in the opening; a first conduction type semiconductor layer on the buffer layer; an active layer on the first conduction type semiconductor layer; a second conduction type semiconductor layer on the active layer; a second electrode on the second conduction type semiconductor layer; and a first electrode on a lower surface of the buffer layer.

An embodiment of the present invention provides a method for manufacturing a light emitting device, the method comprising: selectively etching a substrate to form a first opening and a second opening; forming a buffer layer in the first opening; forming a first conduction type semiconductor layer on the buffer layer; forming an active layer on the first conduction type semiconductor layer; forming a second conduction type semiconductor layer on the active layer; and forming a second electrode on the second conduction type semiconductor layer.

It is to be understood that both the foregoing general description and the following detailed description of embodiment are exemplary and explanatory and are intended to provide further explanation of the invention as claimed.

### BRIEF DESCRIPTION OF THE DRAWINGS

The accompanying drawings, which are included to provide a further understanding of the embodiment and are incorporated in and constitute a part of this application, illustrate embodiment(s) and together with the description serve to explain the principle of the embodiment. In the drawings:

FIGS. 1 to 6 are views for explaining a light emitting device according to embodiments of the present invention; and

FIGS. 7A to 7D are views for explaining a method for manufacturing a light emitting device according to an embodiment of the present invention.

### DETAILED DESCRIPTION

Reference will now be made in detail to the preferred embodiments, examples of which are illustrated in the accompanying drawings.

It will also be understood that when a layer (or film) is referred to as being ‘on/under’ another layer or substrate, it can be directly on/under the other layer or substrate, or intervening layers may also be present.

FIGS. 1 to 6 are views for explaining a light emitting device according to embodiments of the present invention.

Referring to FIG. 1, a light emitting device 101 can include an undoped nitride layer 130 formed on a substrate 110, a first conduction type nitride semiconductor layer 140 on the undoped nitride layer 130, an active layer 150 on the first conduction type nitride semiconductor layer 140, and a second conduction type nitride semiconductor layer 160 on the active layer 150.

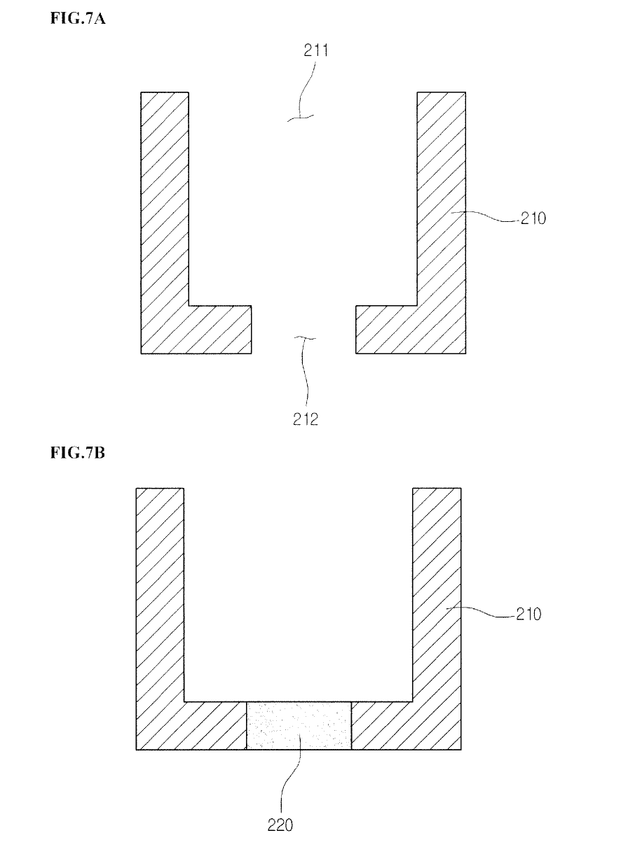

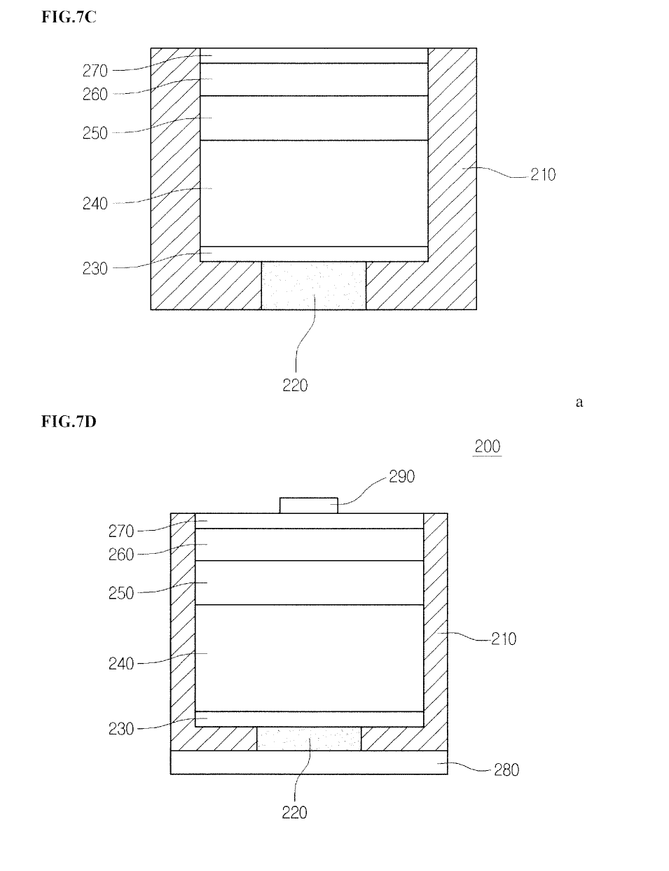

A buffer layer 120 can be formed under a lower surface of the undoped nitride layer 130. The buffer layer 120 can be formed in a lower opening (shown as 212 of FIG. 7A) formed in the substrate 110.

A first electrode 180 can be formed under a lower surface of the buffer layer 120. A second electrode 190 can be formed on an upper surface of the second conduction type nitride semiconductor layer 160.

In detail, the substrate 110 includes an upper opening (shown as 211 of FIG. 7A), and a lower opening (shown as 212 of FIG. 7A). The upper opening 211 has a wider area than that of the lower opening 212. That is, referring to the cross-sectional view of FIG. 1, the width and height of the upper opening 211 formed within the substrate 110 is greater than that of the lower opening 212 formed within the substrate 110.

Each of the buffer layer 120, the undoped nitride layer 130, the first conduction type nitride semiconductor layer 140, the active layer 150, and the second conduction type nitride semiconductor layer 160 has a lateral side surrounded by the substrate 110.

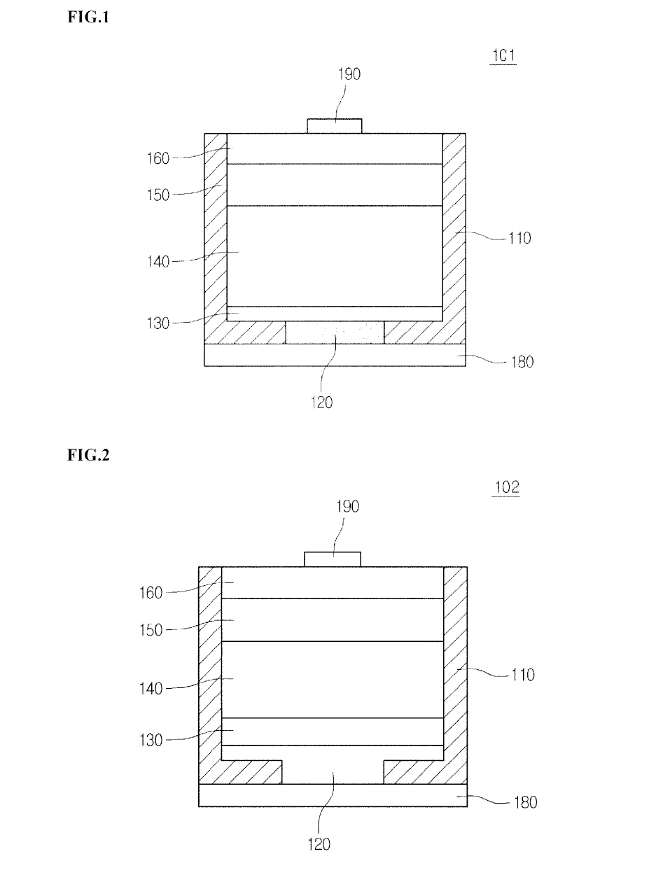

Referring to FIG. 2, unlike the light emitting device 101 according to the first embodiment, the light emitting device 102 according to the second embodiment includes a buffer layer 120 formed in the lower opening 212 and on an upper surface of a substrate 110 defining the lower opening 212.

Therefore, an undoped nitride layer 130 is formed on the buffer layer 120 formed on the substrate 110 within the upper opening 211.

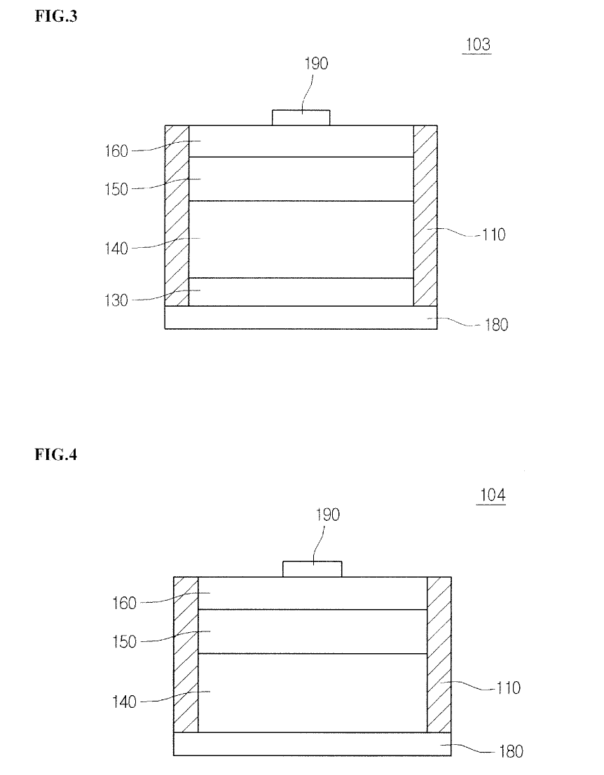

Referring to FIG. 3, a light emitting device 103 according to a third embodiment includes an undoped nitride layer 130, a first conduction type nitride semiconductor layer 140 on the undoped nitride layer 130, an active layer 150 on the first conduction type nitride semiconductor layer 140, and a second conduction type nitride semiconductor layer 160 on the active layer 150.

A first electrode 180 can be formed under a lower surface of the undoped nitride layer 130, and a second electrode 190 is formed on an upper surface of the second conduction type nitride semiconductor layer 160.

Each of the undoped nitride layer 130, the first conduction type nitride semiconductor layer 140, the active layer 150, and the second conduction type nitride semiconductor layer 160 has a lateral side surrounded by the substrate 110.

The light emitting device 103 according to the third embodiment can differ from the light emitting devices 101 and 102 because a portion of the substrate 110, the buffer layer 120 and a portion of the undoped nitride layer 130 are removed, and the first electrode 180 is formed under a lower surface of the undoped nitride layer 130.

Referring to FIG. 4, a light emitting device 104 according to a fourth embodiment includes a first conduction type nitride semiconductor layer 140, an active layer 150 on the first conduction type nitride semiconductor layer 140, and a second conduction type nitride semiconductor layer 160 on the active layer 150.

A first electrode 180 is formed under a lower surface of the first conduction type nitride semiconductor layer 140, and a second electrode 190 is formed on an upper surface of the second conduction type nitride semiconductor layer 160.

Each of the first conduction type nitride semiconductor layer 140, the active layer 150, and the second conduction type nitride semiconductor layer 160 has a lateral side surrounded by the substrate 10.

The light emitting device 104 according to the fourth embodiment can differ from the light emitting devices 101 and 102 because a portion of the substrate 110, the buffer layer 120, the undoped nitride layer 130 and a portion of the first conduction type nitride semiconductor layer 140 are removed, and the first electrode 180 is formed under a lower surface of the first conduction type nitride semiconductor layer 140.

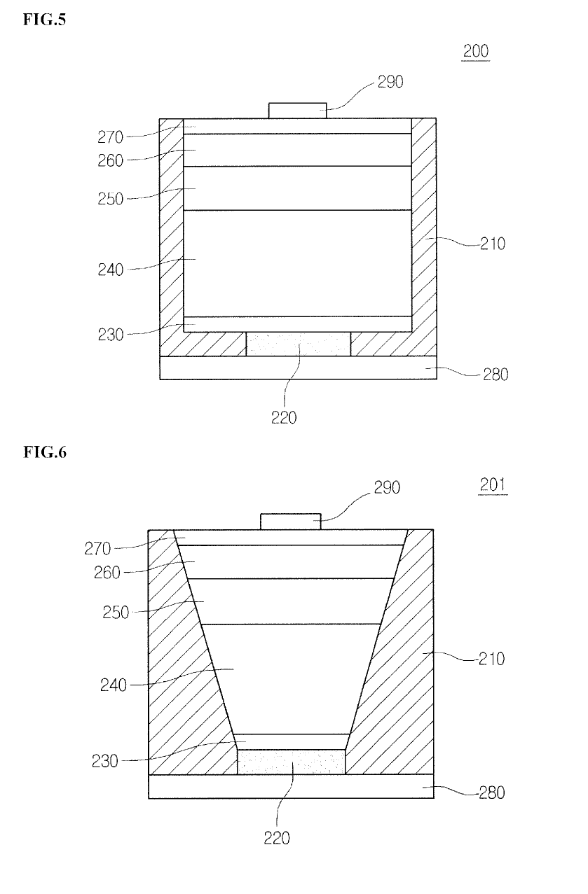

Referring to FIG. 5, a light emitting device 200 according to a fifth embodiment includes an undoped nitride layer 230 formed on a substrate 210, a first conduction type lower nitride semiconductor layer 240 on the undoped nitride layer 230, an active layer 250 on the first conduction type lower nitride semiconductor layer 240, a second conduction type nitride semiconductor layer 260 on the active layer 250, and a first conduction type upper nitride semiconductor layer 270 on the second conduction type nitride semiconductor layer 260.

A buffer layer 220 can be formed under a lower surface of the undoped nitride layer 230. The buffer layer 220 can be formed in a lower opening 212 formed in the substrate 210.

A first electrode 280 can be formed under a lower surface of the buffer layer 220, and a second electrode 290 is formed on an upper surface of the first conduction type upper nitride semiconductor layer 270.

In more detail, an upper opening (shown as 211 of FIG. 7A) and a lower opening (shown as 212 of FIG. 7A) can be formed in the substrate 210. The upper opening 211 has a wider area than that of the lower opening 212. That is, referring to the cross-sectional view of FIG. 5, the width and height of the upper opening 211 formed in the substrate 210 is greater than that of the lower opening 212 formed in the substrate 210.

Each of the buffer layer 220, the undoped nitride layer 230, the first conduction type lower nitride semiconductor layer 240, the active layer 250, the second conduction type nitride semiconductor layer 260, and the first conduction type upper nitride semiconductor layer 270 has a lateral side surrounded by the substrate 210.

The light emitting device 200 according to the fifth embodiment can be formed similar to forming the light emitting device 101 of FIG. 1 with the addition of forming a first conduction type upper nitride semiconductor layer 270 between the second conduction type nitride semiconductor layer (160 of FIG. 1) and the second electrode (190 of FIG. 1).

Likewise, a first conduction type upper nitride semiconductor layer 270 can be formed between the second conduction type nitride semiconductor layer 160 and the second electrode 190 of the light emitting devices 102, 103, and 104 according to the second and fourth embodiments illustrated in FIGS. 2 to 4.

Referring to FIG. 6, a light emitting device 201 according to a sixth embodiment can have a similar structure to that of the light emitting device 200 according to the fifth embodiment illustrated in FIG. 5.

However, the substrate 210 of FIG. 6 can have a structure different from that of the substrate 210 illustrated in FIG. 5. Here, in a specific embodiment, at least a portion of the inner surface of the substrate 210 can be inclined. Referring to FIG. 6, the inner surface of the substrate 210 that is located at a portion where, for example, a buffer layer 220 is formed can remain not inclined, while the remaining inner surface of the opening in the substrate 210 can be inclined.

That is, the substrate 210 can have an upper opening 211 and a lower opening 212, where the upper opening 211 can have an area increasing toward an upper direction. That is, at least a portion of the opening formed in the substrate 210 has an area increasing toward the upper direction.

In many embodiments of the present invention, the inner surface of the substrate 210 can have an inclination angle of 10-80° with respect to a horizontal plane.

The at least partially inclined structure of the substrate 210 illustrated in the light emitting device 201 according to the sixth embodiment of FIG. 6 can be applied to the substrates 110 and 210 illustrated in FIGS. 1 to 5.

Light emitting devices according to embodiments of the present invention and illustrated with reference to FIGS. 1-6 will be described in further detail below.

In a preferred embodiment, the substrate 110, 210 can be formed of SiC or Si.

The buffer layer 120, 220 can be formed for reducing a difference in a lattice constant between the substrate 110, 210, and a first conduction type nitride semiconductor layer 140 or a first conduction type lower nitride semiconductor layer 240. The buffer layer 120, 220 can have a stacked structure. For example, a buffer layer can be a structure selected from an AlInN structure, an InGaN/GaN super lattice structure, an InₓGa₁₋ₓN/GaN stacked structure, and an AlₓIn_{y}Ga_{1-x,y}N/InₓGa₁₋ₓN/GaN stacked structure.

The undoped nitride layer 130, 230 can be an undoped GaN layer.

The first conduction type nitride semiconductor layer 140 and the first conduction type lower nitride semiconductor layer 240 can be an n-GaN layer containing n-type dopants. In a specific embodiment, the n-GaN layer can be doped with Si to reduce a driving voltage.

The active layer 150, 250 can be formed in a single quantum well structure or a multiple quantum well structure so that light is generated by recombination of an electron and a hole. For example, the active layer can be formed in a structure of an InGaN well layer and/or an InGaN barrier layer.

The second conduction type nitride semiconductor layer 160, 260 can be a p-GaN layer containing p-type dopants. In a specific embodiment, the p-GaN layer can be doped with Mg.

The first conduction type upper nitride semiconductor layer 270 can be an n-GaN layer containing n-type dopants.

One or both the first electrode 180, 280 and the second electrode 190, 290 can be a transparent electrode, and can be formed of a material containing at least one of ITO, ZnO, RuOₓ, TiOₓ, and IrOₓ.

The first electrode 180, 280 can be electrically connected to the first conduction type nitride semiconductor layer 140 or the first conduction type lower nitride semiconductor layer 240 for applying power. The second electrode 190, 290 can be electrically connected to the second conduction type nitride semiconductor layer 160, 260 for applying power.

The light emitting devices according to embodiments of the present invention have vertically arranged first electrodes 180, 280 and second electrodes 190, 290.

In addition, referring to FIGS. 1-6, alight emitting device can include a first electrode 180, 280, a first conduction type nitride semiconductor layer 140 or a first conduction type lower nitride semiconductor layer 240, an active layer 150, 250, a second conduction type nitride semiconductor layer 160, 260, and a second electrode 190, 290 vertically arranged, where at least a portion of these layers are located along a vertical line.

Therefore, the light emitting devices according to embodiments of the present invention can provide a uniform carrier supply, and enhance an ESD characteristic. Particularly, since the first electrodes 180, 280 can be located at the lower central side of the first conduction type nitride semiconductor layer 140 or the first conduction type lower nitride semiconductor layer 240, uniform power can be supplied to the first conduction type nitride semiconductor layer 140 or the first conduction type lower nitride semiconductor layer 240, respectively.

Also, in light emitting devices according to embodiments of the present invention, at least a portion of the buffer layer 120, 220 can be formed in an opening in the substrate 110, 210, that is, the lower opening 212 of the substrate 110, 210.

The buffer layer 120, 220 can reduce propagation of dislocation generated at the substrate 110, 210.

In addition, in light emitting devices according to embodiments of the present invention, each of at least the first conduction type nitride semiconductor layer 140 (the first conduction type lower nitride semiconductor layer 240), the active layer 150, 250, and the second conduction type nitride semiconductor layer 160, 260 has a lateral side surrounded by the substrate 110, 210.

In a further embodiment, the substrate 210 can have an inner surface, at least a portion of which is inclined. That is, for a substrate 210 having an upper opening 211 and a lower opening 212, the upper opening 211 can have an area increasing toward an upper direction.

Since light generated at the active layer 150, 250 can be reflected by the inner surface of the substrate 210, a light emitting direction can be controlled or light emitting efficiency can be increased.

The first to sixth embodiments provide light emitting devices having either a pn junction or an npn junction. Technical characteristics disclosed in embodiments regarding a light emitting device 200, 201 having the npn junction can be applied likewise to an embodiment regarding a light emitting device 101, 102, 103, and 104 having the pn junction.

FIGS. 7A to 7D are views for explaining a method for manufacturing a light emitting device according to an embodiment of the present invention.

Embodiments illustrated in FIGS. 7A to 7D exemplarily illustrate a method for manufacturing the light emitting device 200 of FIG. 5, and can be applied likewise to the method for manufacturing the light emitting devices illustrated in FIGS. 1 to 4, and 6.

Referring to FIG. 7A, a substrate 210 can be prepared.

The substrate 210 has an upper opening 211 and a lower opening 212 so that a hole passing through the upper side and the lower side is formed.

That is, the substrate 210 having the upper opening 211 and the lower opening 212 can be formed by selectively etching a substrate.

To form the upper opening 211 and the lower opening 212, photolithography and etching can be performed. The etching can be wet etching or dry etching. In an embodiment, a HF solution can be used for the wet etching.

Referring to FIG. 7B, a buffer layer 220 can be grown in the lower opening 212 of the substrate 210. As illustrated in FIG. 2, the buffer layer 220 can be grown in the lower opening 212 and on an upper surface of the substrate (shown as 110 in FIG. 2) defining the lower opening 212.

The buffer layer 220 can be a multiple layer.

For example, to form a multiple layer buffer layer 220, the substrate 210 can be mounted in a metal organic chemical vapor deposition (MOCVD) chamber or a molecular beam epitaxy (MBE) chamber, silicon can be grown up to a thickness of about 10 Å on the substrate 210 under atmosphere of SiH₄ at temperature of 500-600° C. to form a silicon layer. Then, an InN layer can be formed on the silicon layer.

Further an AlN layer containing Al and N at a predetermined ratio can be grown using trimethylaluminum (TMAl) and NH₃ on the InN layer at a temperature of about 1000° C.

Therefore, by following the above steps, the buffer layer 220 is formed as a multiple layer including a silicon layer, an InN layer, and an AlN layer.

Referring to FIG. 7C, an undoped nitride layer 230 can be formed on the buffer layer 220.

The undoped nitride layer 230 can be formed by supplying NH₃ and TMGa at a growing temperature of 1050° C., and growing an undoped GaN layer containing no dopants to a predetermined thickness.

Then, a first conduction type lower nitride semiconductor layer 240 can be formed on the undoped nitride layer 230.

The first conduction type lower nitride semiconductor layer 240 can be formed by supplying NH₃, TMGa, and a silane gas containing n-type dopants such as Si and growing an n-GaN layer to a predetermined thickness.

An active layer 250 can be formed on the first conduction type lower nitride semiconductor layer 240. The active layer 250 can be formed of InGaN.

In an embodiment, the active layer 250 can be formed by supplying NH₃, TMGa, and TMIn using a nitrogen gas as a carrier gas at a temperature of 780° C., and growing an InGaN layer to a thickness of 30-1200 Å.

At this point, the active layer 250 can be formed in a multiple stacked structure by growing respective elements of InGaN with different mol ratios.

Also, a barrier layer can be formed on the active layer 250. For example, a p-type cladding layer for carrier confinement can be formed between the active layer 250 and a second conduction type nitride semiconductor layer 260.

Also, the second conduction type nitride semiconductor layer 260 can be formed on the active layer 250.

The second conduction type nitride semiconductor layer 260 can be a p-GaN layer containing p-type dopants.

The p-GaN layer can contain Mg as impurities. After the p-GaN layer is formed, the p-GaN layer can be heat-treated at a temperature of 500-900° C. so that the p-GaN layer has maximum hole concentration.

The second conduction type nitride semiconductor layer 260 can be formed as a p-GaN layer such as an AlGaN layer by supplying TMGa, TMA, bis(cyclopentadienyl) magnesium (Cp₂Mg), {(C₅H₅)₂Mg}, and NH₃ using hydrogen as a carrier gas at an atmosphere temperature of 1000° C.

The first conduction type upper nitride semiconductor layer 270 can be formed on the second conduction type nitride semiconductor layer 260.

Like the first conduction type lower nitride semiconductor layer 240, the first conduction type upper nitride semiconductor layer 270 can be formed by supplying NH₃, TMGa, and a silane gas containing n-type dopants such as Si and growing an n-GaN layer to a predetermined thickness of 1-10000 Å.

Also, the second electrode 290 can be formed on the first conduction type upper nitride semiconductor layer 270, and the first electrode 280 can be formed on the lower surface of the buffer layer 220.

Alternatively, instead of forming the first electrode 280 on the lower surface of the buffer layer 220, the first electrode 280 can be formed on the lower surface of the undoped nitride layer 230 by removing a portion of the substrate 210, and portions of the buffer layer 220 and the undoped nitride layer 230.

Also, instead of forming the first electrode 280 on the lower surface of the buffer layer 220, the first electrode 280 can be formed on the lower surface of the first conduction type lower nitride semiconductor layer 240 by removing a portion of the substrate 210, and portions of the buffer layer 220, the undoped nitride layer 230, and the first conduction type lower nitride semiconductor layer 240.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device, comprising:
a first electrode;
a first conduction type semiconductor layer on the first electrode;
an active layer on the first conduction type semiconductor layer;
a second conduction type semiconductor layer on the active layer;
a second electrode on the second conduction type semiconductor layer; and
a substrate on lateral sides of the first conduction type semiconductor layer, the active layer, and the second conduction type semiconductor layer.

2. The light emitting device according to claim 1, further comprising an undoped nitride layer formed between the first electrode and the first conduction type semiconductor layer.

3. The light emitting device according to claim 1, wherein the substrate surrounds the lateral sides of the first conduction type semiconductor layer, the active layer, and the second conduction type semiconductor layer.

4. The light emitting device according to claim 1, wherein the substrate has an inclined inner surface.

5. The light emitting device according to claim 1, wherein the first electrode, the first conduction type semiconductor layer, the active layer, the second conduction type semiconductor layer, and the second electrode are vertically arranged.

6. The light emitting device according to claim 1, further comprising a buffer layer formed between the first electrode and the first conduction type semiconductor layer.

7. The light emitting device according to claim 1, further comprising a first conduction type upper semiconductor layer formed between the second conduction type semiconductor layer and the second electrode.

8. A light emitting device, comprising:
a substrate having an opening;
a buffer layer in the opening;
a first conduction type semiconductor layer on the buffer layer;
an active layer on the first conduction type semiconductor layer;
a second conduction type semiconductor layer on the active layer;
a second electrode on the second conduction type semiconductor layer; and
a first electrode under a lower surface of the buffer layer.

9. The light emitting device according to claim 8, further comprising an undoped nitride layer formed between the buffer layer and the first conduction type semiconductor layer.

10. The light emitting device according to claim 8, wherein the substrate surrounds lateral sides of the buffer layer, the first conduction type semiconductor layer, the active layer, and the second conduction type semiconductor layer.

11. The light emitting device according to claim 8, wherein the substrate has an inclined inner surface along at least a portion of the opening.

12. The light emitting device according to claim 8, wherein the first electrode, the buffer layer, the first conduction type semiconductor layer, the active layer, the second conduction type semiconductor layer, and the second electrode are vertically arranged.

13. The light emitting device according to claim 8, wherein at least a portion of each of the first electrode, the buffer layer, the first conduction type semiconductor layer, the active layer, the second conduction type semiconductor layer, and the second electrode is located along a same vertical line.

14. The light emitting device according to claim 8, further comprising a first conduction type upper semiconductor layer formed between the second conduction type semiconductor layer and the second electrode.

15. The light emitting device according to claim 8, wherein the opening comprises a lower opening in which the buffer layer is formed, and an upper opening in which the first conduction type semiconductor layer, the active layer, and the second conduction type semiconductor layer are formed, wherein the upper opening has a wider area than that of the lower opening.

16. A method for manufacturing a light emitting device, the method comprising:
selectively etching a substrate to form a first opening and a second opening;
forming a buffer layer in the first opening;
forming a first conduction type semiconductor layer on the buffer layer;
forming an active layer on the first conduction type semiconductor layer;
forming a second conduction type semiconductor layer on the active layer; and
forming a second electrode on the second conduction type semiconductor layer,
wherein the first conduction type semiconductor layer, the active layer, and the second conduction type semiconductor layer are formed in the second opening.

17. The method according to claim 16, further comprising forming a first electrode under the buffer layer.

18. The method according to claim 16, further comprising:
etching a portion of the substrate and the buffer layer, and
forming a first electrode under the first conduction type semiconductor layer.

19. The method according to claim 16, further comprising, before the forming of the second electrode, forming a first conduction type upper semiconductor layer on the second conduction type semiconductor layer.

20. The method according to claim 16, further comprising forming an undoped nitride layer between the buffer layer and the first conduction type semiconductor layer;
etching a portion of the substrate and the buffer layer; and
forming a first electrode under the undoped nitride layer.
